(19) United States
(12) Patent Application Publication
(10) Pub. No.: US 2026/0056228 A1
(43) Pub. Date: Feb. 26, 2026

(54) SIGNAL TRSANSMISSION CONNECTOR

(71) Applicant: TSE CO., LTD., Chungcheongnam-do (KR)

(72) Inventors: Hoe Sik Moon, Chungcheongnam-do (KR); Bo Hyun Kim, Chungcheongnam-do (KR); Yun Chan Nam, Chungcheongnam-do (KR)

(21) Appl. No.: 19/302,231

(22) Filed: Aug. 18, 2025

(30) Foreign Application Priority Data
Aug. 22, 2024 (KR) 10-2024-0112575

(51) Int. Cl. G01R 1/04; G01R 31/28

(52) U.S. Cl. CPC G01R 1/0466; G01R 1/0458; G01R 31/2884; G01R 31/2896

(57) ABSTRACT

The present disclosure relates to a signal transmission connector having electro-conductive members supported by a support member and spaced apart from inner walls of housing holes formed in an upper housing and a lower housing, a rubber ring is disposed in a space between the electro-conductive member and the inner wall of each housing hole of the upper or lower housing, surrounds the electro-conductive member, and comes in contact with the inner wall of the upper or lower housing to align the electro-conductive member, so the shift contact between the terminal of the test device or the pad of the test board and the electro-conductive member are prevented and it is possible to prevent foreign substances from entering the inside of the signal transmission connector.

### CROSS-REFERENCE TO RELATED APPLICATION

This application claims priority of Korean Patent Application No. 10-2024-0112575, filed on August 22, 2024 , in the KIPO (Korean Intellectual Property Office), the disclosure of which is incorporated herein entirely by reference.

### BACKGROUND OF THE INVENTION

### FIELD OF THE INVENTION

The present disclosure relates to a signal transmission connector, and more specifically, to a signal transmission connector configured to be connected to an electronic component such a semiconductor package for transmitting an electrical signal, and a method for manufacturing the same.

### DESCRIPTION OF THE RELATED ART

Currently, various types of connectors for transmitting an electrical signal have been used in various fields such as electronic or semiconductor industries.

In the case of semiconductor devices, they are manufactured through a front-end-of-line (FEOL), a back-end-of-line (BEOL), and a test process, and among these processes, the test process is a process for testing whether the semiconductor device is being normally operated to sort normal products and defective products.

One of the key components applied to the test process is a signal transmission connector called a test socket. The test socket is mounted on a test board electrically connected to a test provided for testing an integrated circuit tester, and is used to inspect semiconductor devices. The test socket is equipped with a contact pin, and this contact pin electrically connects a terminal (lead) of the semiconductor device and a terminal of the printed circuit board. The test board generates an electrical signal for testing the semiconductor device to be connected to the test socket, outputs it to the semiconductor device, and then uses the electrical signal input through the semiconductor device to test whether the semiconductor device is being normally operated. Based on the test results, the semiconductor device is determined as either good or defective.

Typically, a pogo socket and a rubber socket have been used as the test socket.

The pogo socket is made by assembling pogo pins, which are individually manufactured, into a housing. Recently, the demand for rubber sockets has been increased in the semiconductor device test process due to problems such as damage to a package ball, an increased unit price, or the like.

The rubber socket has a configuration in which electro-conductive parts, each of which having a plurality of electro-conductive particles contained in an elastic material such as silicon, are insulated from each other and disposed at an inside of an insulating part made of an elastic material such as silicon. Such rubber socket has the characteristic of exhibiting conductivity only in a thickness direction, and has the advantage of excellent durability and achieving simple electrical connection since no mechanical means such as soldering or springs are used therein. In addition, since the rubber socket can absorb mechanical shock or deformation, this has the advantage of being capable of being connected smoothly to a semiconductor device, etc.

Since the conventional signal transmission connector consisting of the rubber socket has a configuration in which the electro-conductive parts are structurally connected to each other through an insulating part, a pressurizing force (or stroke) applied to one electro-conductive part has also influence on another adjacent electro-conductive parts through the insulating part. Therefore, if there is a tolerance in the height of the semiconductor package terminal or there is warpage in the semiconductor package, there is a problem in that there are difference in the degree of compression applied to the electro-conductive parts, so the electro-conductive part subject to concentrated stress is broken or a contact failure in which the terminal does not come into contact with the electro-conductive part may occur.

Hence, a rubber socket in which the electro-conductive part is independently operated has recently been developed. FIG. 1 illustrates a conventional signal transmission connector 70 disclosed in Korean Patent Application No. 10-2024-0009150 invented by the present inventors, the signal transmission connector has an electro-conductive part that is independently operated.

The conventional signal transmission connector 70 is a connector configured to connect terminals 11 of a device 10 under test to a pad (not shown) of a test board generating a test signal, for performing an electrical test for the device under test, this signal transmission connector includes a plurality of electro-conductive members 30, each of which being formed of an elastic insulating material in which a plurality of electro-conductive particles are arranged in a thickness direction, and having a truncated conical upper bump 31 being able to come into contact with the terminal of the device under test, an inversed truncated conical lower bump 32 being able to come into contact with the pad of the test board, and a cylindrical connecting bump 33 extending between the upper bump and the lower bump; an insulating support member 40 having an upper surface 42 and an opposite lower surface 43, and provided with a plurality of support holes 41 formed therein, each of the support holes being coupled with the corresponding connecting bump; an upper housing 50 formed of an inelastic material, attached to the upper surface of the support member, and having a plurality of upper housing holes 51, an inner wall constituting each upper housing hole being spaced apart from and surrounding the corresponding upper bump; and a lower housing 60 formed of an inelastic material, attached to the lower surface of the support member, and having a plurality of lower housing holes, an inner wall constituting each lower housing hole being spaced apart from and surrounding the corresponding lower bump.

In the conventional signal transmission connector 70 configured as above, since the electro-conductive members are disposed and spaced apart from each other in the upper and lower housings made of an inelastic material, during the test for the device under test, when the terminals of the device under test pressurize the electro-conductive members, the electro-conductive members are compressed independently without affecting each other and becomes a state in which electricity pass therethrough, so the influence of adjacent electro-conductive members can be minimized during the test. The overall permittivity is reduced by the air layer with the relative permittivity of 1 with which the separated space is filled, thereby minimizing signal interference between the electro-conductive members. As a result, this signal transmission connector can also be useful for high-speed signal transmission.

FIG. 2 is a drawing for illustrating problems with the conventional signal transmission connector 70. FIG. 2 exemplarily illustrates the shift contact generated in the electro-conductive member indicated by “S” and foreign substances P entering a space between the upper bump and the upper housing.

In the conventional signal transmission connector 70, since the upper bump and the lower bump of the electro-conductive member, which are disposed in the housing hole and is spaced apart from an inner wall of the housing hole, are supported only at a portion where they are connected by the connecting bump, during numerous testing processes, the upper or lower bumps may not be located in a correct position. The upper bump or the lower bump, which is not located in a correct position, causes a so-called shifted contact in which the bump does not come into contact with the terminal of the device under test or the pad of the test board in correct position, but rather comes into contact incorrectly with it with an error. Due to this shift contact, the contact resistance between the terminal and the electro-conductive member, or between the electro-conductive member and the pad is increased, degrading the signal quality of the signal transmission connector.

Furthermore, in the conventional signal transmission connector 70, since the upper bump of the electro-conductive member is disposed in the upper housing hole and is spaced apart from the inner wall of the upper housing hole, the space between the upper housing and the upper bump is opened to the outside, and this configuration allows foreign substances P such as dust to enter this space. Similarly, foreign substances P can also enter a space between the lower housing and the lower bump. If foreign substances enter the space between the upper housing and the upper bump or the space between the lower housing and the lower bump, the electro-conductive member is contaminated, and a contact between the electro-conductive member and foreign substances causes current leakage, degrading the signal quality of the signal transmission connector.

### SUMMARY OF THE INVENTION

The present disclosure is conceived in view of the above-described problems, and an object of the present disclosure is to provide a signal transmission connector provided with a rubber ring capable of aligning an electro-conductive member in a correct position and preventing foreign substances from flowing towards the electro-conductive member.

In order to achieve the above object, a signal transmission connector according to the present disclosure is a signal transmission connector connecting terminals of a device under test to pads of a test board, which generates a test signal, to perform an electrical test for the device under test, the signal transmission connector may include a plurality of electro-conductive members, each of electro-conductive members being formed of an elastic insulating material in which a plurality of electro-conductive particles are arranged in a thickness direction, and having a truncated conical upper bump being able to come into contact with the terminal, an inversed truncated conical lower bump being able to come into contact with the pad, and a cylindrical connecting bump extending between the upper bump and the lower bump; an insulating support member having an upper surface and an opposite lower surface, and provided with a plurality of support holes formed therein, each of the support holes being coupled with the corresponding connecting bump; an upper housing formed of an inelastic material, attached to the upper surface of the support member, and having a plurality of upper housing holes, an inner wall constituting each upper housing hole being spaced apart from and surrounding the corresponding upper bump; and a lower housing formed of an inelastic material, attached to the lower surface of the support member, and having a plurality of lower housing holes, an inner wall constituting each lower housing hole being spaced apart from and surrounding the corresponding lower bump, wherein a plurality of upper rubber rings are disposed in the upper housing holes, respectively, each of the upper rubber rings has a thickness smaller than that of the upper bump, surrounds an outer circumferential surface of the upper bump, and is in contact with an inner wall of the upper housing hole.

The upper rubber ring may be disposed at an upper side of the upper housing hole.

The upper rubber ring may be formed integrally with the upper bump.

A plurality of upper rubber rings may be disposed in the lower housing holes, respectively, each of the lower rubber rings may have a thickness smaller than that of the lower bump, surround an outer circumferential surface of the lower bump, and be in contact with an inner wall of the lower housing hole.

The lower rubber ring may be disposed at a lower side of the lower housing hole.

The lower rubber ring may be formed integrally with the lower bump.

The upper housing and the lower housing may be made of an insulating material.

The upper housing and the lower housing may be made of an electro-conductive material, an insulating layer may be formed on an inner wall of each of the upper housing holes and the lower housing holes, and the upper rubber ring may be in contact with an inner circumferential surface of the insulating layer.

In the signal transmission connector according to the present disclosure, Since the upper bump or the lower bump of the electro-conductive member is aligned in the upper housing or the lower housing by the rubber ring, the upper bump or the lower bump may be located in a correct position to prevent the shift contact from occurring between the terminal of the device under test or the pad of the test board.

In addition, in the signal transmission connector according to the present disclosure, the rubber ring blocks the space, which is opened to the outside between the upper housing and the upper bump or between the lower housing and the lower bump, it is possible to prevent foreign substances from flowing towards the electro-conductive member, thereby preventing the electro-conductive member from being contaminated as much as possible.

Therefore, in the signal transmission connector according to the present disclosure, the contact stability between the connector and the terminal of the test device or between this connector and the pad of the test board is improved, and the elector-conductivity of the electro-conductive members is maintained to the maximum, so it is possible to secure the reliability of the signal transmission connector.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 is a view illustrating a conventional signal transmission connector;

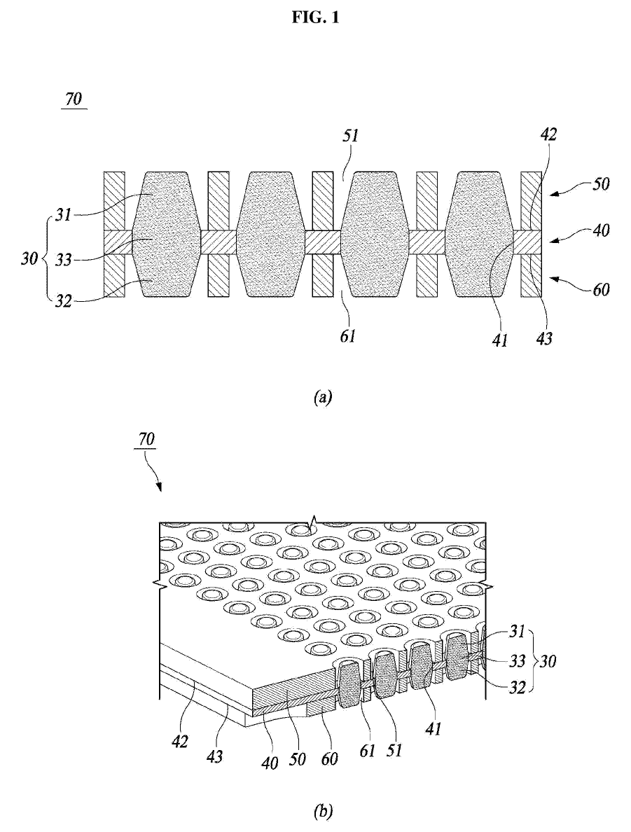

FIG. 2 is a view for describing problems of the conventional signal transmission connector;

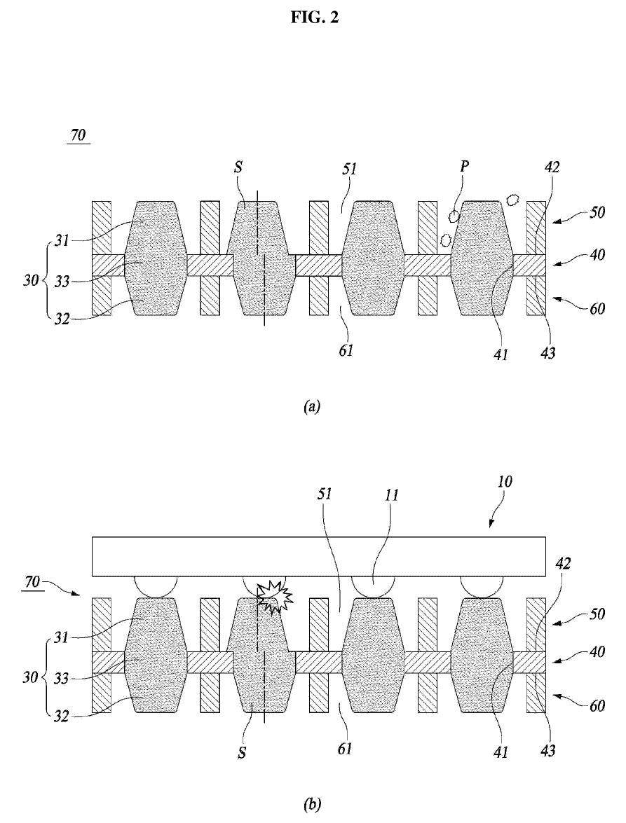

FIG. 3 is a view illustrating a signal transmission connector according to one embodiment of the present disclosure, wherein a is a cross-sectional view and b is a sectional-perspective view;

FIG. 4 is a view illustrating an upper rubber ring and a lower rubber ring according to one embodiment of the present disclosure;

FIGS. 5 and 6 are views illustrating modified examples of the signal transmission connector according to one embodiment of the present disclosure; and

FIG. 7 is a view illustrating a test process using the signal transmission connector according to one embodiment of the present disclosure.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms "a", "an" and "the" are intended to include the plural forms as well, unless the context clearly indicates otherwise. It will be further understood that the terms “includes”, "comprises" and/or "comprising," when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed "on" a substrate or other layer refers to a layer formed directly on top of the substrate or other layer or to an intermediate layer or intermediate layers formed on the substrate or other layer. It will also be understood by those skilled in the art that structures or shapes that are "adjacent" to other structures or shapes may have portions that overlap or are disposed below the adjacent features.

In this specification, the relative terms, such as "below", "above", "upper", "lower", "horizontal", and "vertical", may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter, a signal transmission connector according to the present disclosure will be described in detail with reference to the drawings.

In the present disclosure, a device under test is placed above a signal transmission connector, and a test board is placed below the signal transmission connector, so an upper portion, an upper surface, an upper side surface, an upper side, an upper end, a lower portion, a lower surface, a lower side surface, a lower side, a lower end, and the like of any component are described on the basis of the above. In addition, the same or similar components are labeled with the same or similar reference numbers, and a description thereon is omitted.

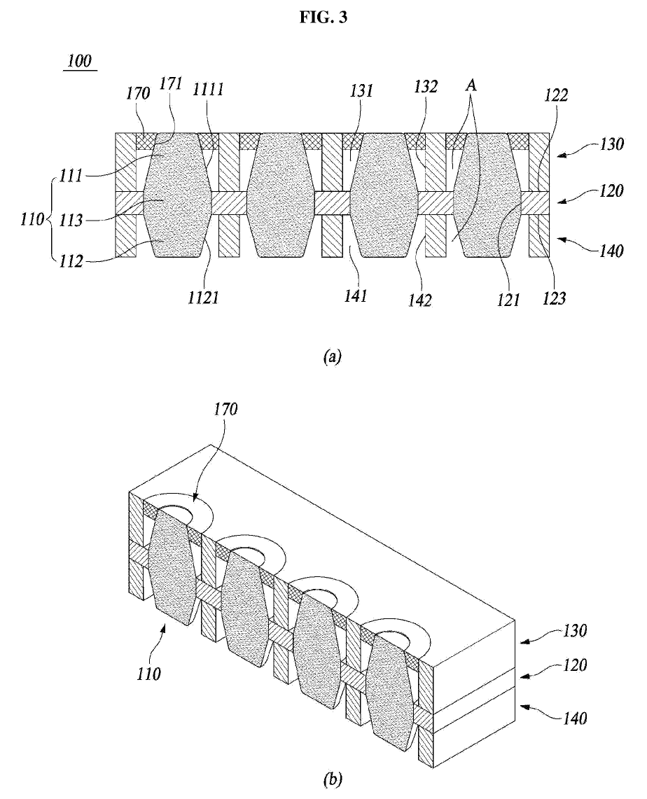

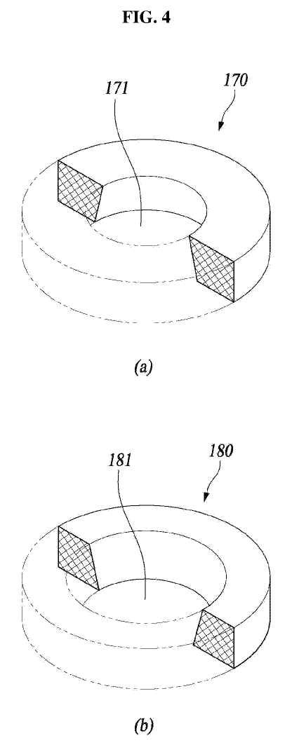

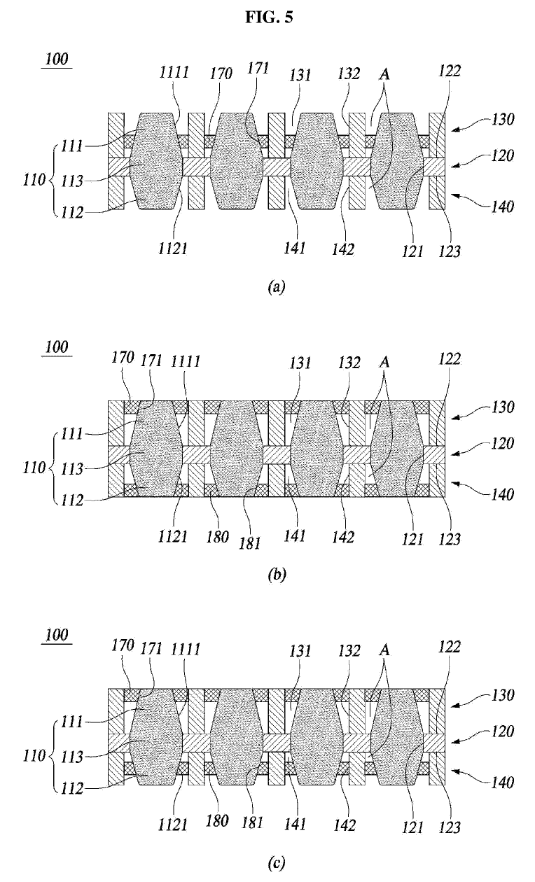

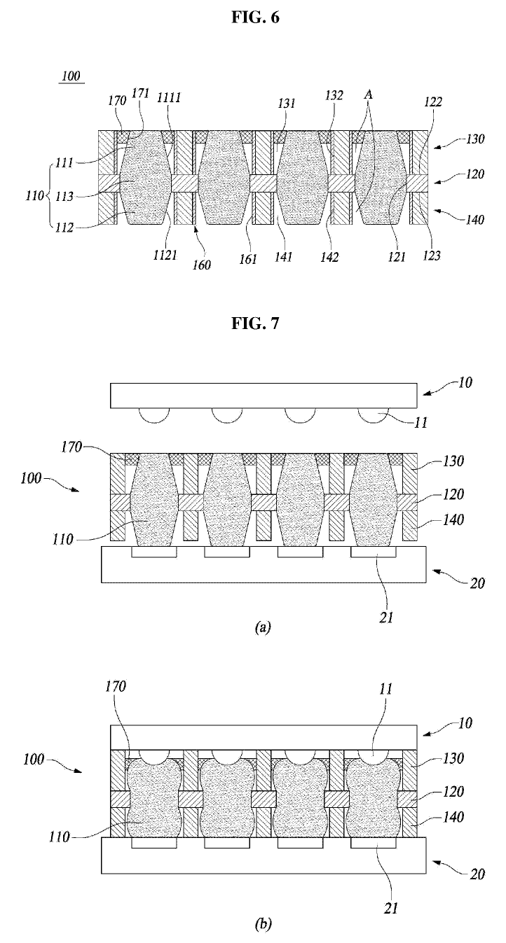

FIG. 3 is a view illustrating a signal transmission connector according to one embodiment of the present disclosure, wherein a is a cross-sectional view and b is a sectional-perspective view, FIG. 4 is a view illustrating an upper rubber ring and a lower rubber ring according to one embodiment of the present disclosure, FIGS. 5 and 6 are views illustrating modified examples of the signal transmission connector according to one embodiment of the present disclosure, and FIG. 7 is a view illustrating a test process using the signal transmission connector according to one embodiment of the present disclosure.

As shown in the drawings, a signal transmission connector 100 according to one embodiment of the present disclosure is a signal transmission connector configured to connect terminals 11 of a device 10 under test to pads 21 of a test board 20 generating a test signal, for performing an electrical test for the device under test, and this signal transmission connector includes a plurality of electro-conductive members 110, each of which being formed of an elastic insulating material in which a plurality of electro-conductive particles are arranged in a thickness direction, and having a truncated conical upper bump 111 being able to come into contact with the terminal, an inversed truncated conical lower bump 112 being able to come into contact with the pad, and a cylindrical connecting bump 113 extending between the upper bump and the lower bump; an insulating support member 120 having an upper surface 122 and an opposite lower surface 123, and provided with a plurality of support holes 121 formed therein, each of the support holes being coupled with the corresponding connecting bump; an upper housing 130 formed of an inelastic material, attached to the upper surface of the support member, and having a plurality of upper housing holes 131, an inner wall constituting each upper housing hole being spaced apart from and surrounding the corresponding upper bump; and a lower housing 140 formed of an inelastic material, attached to the lower surface of the support member, and having a plurality of lower housing holes 141, an inner wall constituting each lower housing hole being spaced apart from and surrounding the corresponding lower bump. Here, the above signal transmission connector is characterized in that upper rubber rings 170 are disposed in the upper housing holes 131, respectively and that each of the upper rubber rings has a thickness smaller than that of the upper bump 111, surrounds an outer circumferential surface 1111 of the upper bump 111, and is in contact with an inner wall 132 of the upper housing hole 131.

In such signal transmission connector 100, the upper bump 111 of the electro-conductive member 100 comes into contact with the terminal of the device under test placed above the upper housing 130 and the lower bump 112 of the electro-conductive member comes into contact with the pad of the test board placed below the lower housing 140 to transmit an electrical signal from the test board to the device under test. Therefore, the signal transmission connector enables the device under test to be tested through the test board, or can electrically connect the device under test to various electronic devices to transmit the electrical signal.

Hereinafter, providing the signal transmission connector 100 according to one embodiment of the present disclosure in the test board 30 to perform a function of transmitting the electrical signal between the test board 20 and the device 10 under test is described as an example.

In the signal transmission connector 100 according to one embodiment of the present disclosure, in order to allow an upper end of each electro-conductive member to be connected to the terminal 11 of the device 10 under test and a lower end to be connected to the pad 21 of the test board 20, each electro-conductive member 110 may be formed in a form in which a plurality of electro-conductive particles are arranged within an elastic insulating material in the thickness direction (i.e., upward and downward direction) of the electro-conductive member. Therefore, the electro-conductive member has elasticity and can elastically come into contact with the terminal 11 of the device under test and the pad 21 of the test board. The plurality of electro-conductive members 110 are formed at positions corresponding to the terminals 11, respectively, which are provided on the device 10 under test and will be connected to the electro-conductive members.

Each of the electro-conductive members 110 includes the upper bump 111 being capable of coming into contact with the terminal 11 of the device under test, the lower bump 112 being capable of coming into contact with the pad 21 of the test board, and the connecting bump 113 extending between the upper bump 111 and the lower bump 112.

The upper bump 111 of the electro-conductive member 110 may be formed into a truncated conical shape, the lower bump 112 may be formed into an inversed truncated conical shape, and the connecting bump 113 may be formed into a cylindrical shape having a width which is the same as those of a lower surface of the upper bump and an upper surface of the lower bump. However, it is also possible to form the connecting bump 113 such that its width is larger than that of the lower surface of the upper bump and the upper surface of the lower bump. If the width of the connecting bump 113 is large, it is easy to align the electro-conductive member 110 with respect to the support hole 121 of the support member 120 when replacing the electro-conductive member individually with new one, so it can be attached and combined at a more accurate position. In this way, the electro-conductive member 110 has a shape in which the connecting bump 113 has the largest width.

As an elastic insulating material constituting the electro-conductive member 110, a heat-resistant polymer material having a cross-linked structure, for example, silicone rubber, polybutadiene rubber, natural rubber, polyisoprene rubber, styrene-butadiene copolymer rubber, acrylonitrile-butadiene copolymer rubber, styrene-butadiene-diene block copolymer rubber, styrene-isoprene block copolymer rubber, urethane rubber, polyester rubber, epichlorohydrin rubber, ethylene-propylene copolymer rubber, ethylene-propylene-diene copolymer rubber, soft liquid epoxy rubber, and the like may be employed.

In addition, as the electro-conductive particles constituting the electro-conductive member 110, the particles having magnetism may be employed such that they may be reacted by a magnetic field. For example, as the electro-conductive particles, particles obtained by plating a surface of core particles, for example, particles of metal exhibiting magnetism, such as iron, nickel, cobalt, etc., or alloy particles thereof, or particles containing these metals, or particles of these metals, with a metal having excellent electrical-conductivity, such as gold, silver, palladium, radium, or the like; particles obtained by plating a surface of core particles, for example, non-magnetic metal particles, inorganic substance particles such as glass beads or the like, and polymer particles, with electro-conductive magnetic substance such as nickel, cobalt, or the like; or particles obtained by plating core particles with electro-conductive magnetic substance and a metal having excellent electrical-conductivity may be employed.

The support member 120 has the lower surface 123 opposing the upper surface 122, and is provided with the support holes 121 formed at positions, which correspond to the electro-conductive members 110, respectively. By coupling the connecting bump 113 to the support hole 121 of the support member, the support member can support the plurality of electro-conductive members 110.

The support member 120 is made of an insulating material, and although it is preferable to use a polyimide sheet as the insulating material, it is also possible to use another insulator if it can support the electro-conductive members. The connecting bump 113 of the electro-conductive member can be coupled to the support hole 121 of the support member by an adhesive, or the connecting bump can be coupled to the support member when the elastic insulating material is cured during a manufacturing process of the connecting bump.

The upper housing 130 is attached to the upper surface 122 of the support member 120, and the lower housing 140 is attached to the lower surface 123 of the support member 120. The upper housing 130 and the lower housing 140 may be attached to the support member 120 with an adhesive, but are not limited thereto, and they may also be fastened using screws or the like.

The upper housing 130 and the lower housing 140 constitute a body of the signal transmission connector 100, and are provided with the upper housing holes 131 and the lower housing holes 141, respectively. The upper housing hole 131 and the lower housing hole 141 corresponding to each other form a space for receiving the electro-conductive member 110 and have diameter larger than that of the electro-conductive member 110.

The upper housing 130 and the lower housing 140 may be made of an inelastic insulating material or an inelastic electro-conductive material. As the inelastic insulating material, engineering plastics such as polyimide, or various other inelastic insulating materials may be used, and electro-conductive metal such as aluminum, copper, brass, SUS, iron, nickel, and the like, or various materials that have both conductivity and inelastic property may be employed as the inelastic electro-conductive material. The upper housing 130 and the lower housing 140 made of such inelastic material have a hardness that prevents compressive deformation, caused by a maximum pressurizing force applied through the device 10 under test during a test process, from occurring, and have a characteristic of not being easily elastically deformed unlike an elastic insulating part of a conventional rubber socket.

If the upper housing 130 and the lower housing 140 are made of an electro-conductive material, it is preferable to form an insulating layer 160 on inner walls of the upper housing hole 131 and the lower housing hole 141, as shown in FIG. 6. This is to prevent electrical shorts from occurring due to direct contact between the electro-conductive member and the upper housing or the lower housing made of an electro-conductive material. Such insulating layer 160 may be formed not only on the inner walls of the upper housing hole 131 and the lower housing hole 141, but also on an upper surface of the upper housing 130 and a lower surface of the lower housing 140, thereby preventing the terminal 11 of the device under test or the pad 21 of the test board from coming into contact with the upper housing or the lower housing made of the electro-conductive material.

The upper housing 130 is disposed on the upper surface 122 of the support member such that the inner wall of each upper housing hole 131 is spaced apart from and surrounds the corresponding upper bump 111 of the electro-conductive member, and the lower housing 140 is disposed on the lower surface 123 of the support member such that the inner wall of each lower housing hole 141 is spaced apart from and surrounds the corresponding lower bump 112 of the electro-conductive member.

The upper housing 130 may have a vertical thickness that is not larger than that of the upper bump 111 or is larger than that of the upper bump 111. A configuration, in which a thickness of the upper bump 111 is larger than that of the upper housing 130 and the upper bump thus protrudes from the upper surface of the upper housing, is useful in a case where the device under test is an LGA (land grid array) terminal because the upper bump can be more easily connected to a flat shaped LGA terminal. On the contrary, in the configuration, in which the upper housing 130 protrudes from the upper bump 111 of the electro-conductive member, a protruding portion of the upper housing 130 may serve as a ball guide to guide the terminal 11 in the form of a BGA (ball grid array), of the device under test towards the upper bump 111 of the electro-conductive member, so this configuration may be usefully applied in a case where an alignment between the terminal 11 of the device under test and the electro-conductive member 110 is particularly necessary.

In addition, it is desirable that the lower housing 140 has a thickness that is not larger than that of the lower bump 112 to enable the lower bump 112 to be stably connected to the pad 21 of the test board.

As illustrated in FIG. 3, the signal transmission connector 100 according to one embodiment of the present disclosure includes upper rubber rings 170, each of which having a thickness smaller than that of the upper bump 111, surrounding the outer circumferential surface 1111 of the upper bump 111, and being in contact with the inner wall 132 of the upper housing hole 131.

The upper rubber ring 170 may be made of silicone rubber. However, the material for the upper rubber ring is not limited to the above, and the upper rubber ring may be made of the same material as the elastic insulating material used for the electro-conductive member 110.

As shown in (a) of FIG. 4, the upper rubber ring 170 has a truncated conical upper ring hole 171 to surround the outer circumferential surface of the upper bump, and its outer circumferential surface is formed into a cylindrical shape to come into contact with the inner wall of the upper housing hole.

This upper rubber ring 170 has a thickness smaller than that of the upper bump 111, so a portion of the upper bump 111 is inserted into the upper ring hole 171. Therefore, during the test, when the terminal of the device under test pressurizes the upper bump, the upper bump and the upper rubber ring come into closely contact with each other in the upper housing hole formed in the upper housing made of an inelastic material, and when the upper bump is compressed downward, the upper rubber ring may also be compressed together with the upper bump.

As shown in FIG. 3, the upper rubber ring 170 may be placed on an upper side of the upper housing hole 131. If the upper bump 111 of the electro-conductive member has a thickness that is the same as that of the upper housing 130 or protrudes upward from the upper housing, the upper rubber ring 170 may be placed in an upper end of the upper housing hole 131 such that an upper surface of the upper rubber ring 170 is flush with a top end of the upper housing hole 131. Furthermore, if the upper bump 111 of the electro-conductive member has a thickness smaller than that of the upper housing 130, the upper rubber ring 170 may be disposed at a corresponding position in the upper housing hole 131 in which the upper surface of the upper rubber ring 170 is flush with the upper surface of the upper bump.

However, the present disclosure is not limited to the above, as shown in (a) of FIG. 5, the upper rubber ring 170 may be placed at an intermediate portion or other portion of the upper housing holes 131 to support the upper bump 111. Moreover, it is also possible to dispose two or more upper rubber rings 170 in one upper housing hole 131.

As shown in (b) and (c) of FIG. 5, the signal transmission connector 100 according to one embodiment of the present disclosure may include lower rubber rings 180, each of which having a thickness smaller than that of the lower bump 112, surrounding an outer circumferential surface 1121 of the lower bump 112, and being in contact with an inner wall 142 of the lower housing hole 141.

The lower rubber ring 180 may be made of the same material as the material constituting the upper rubber ring 170. As shown in (b) of FIG. 5, the lower rubber ring 180 has an inversed truncated conical lower ring hole 181 to surround an outer circumferential surface of the lower bump, and its outer circumferential surface is formed into a cylindrical shape to come into contact with the inner wall of the lower housing hole.

As shown in (b) of FIG. 5, the lower rubber ring 180 may be disposed at a lower side of the lower housing hole 141, and may be disposed at an intermediate portion or other portion of the lower housing hole 141, as shown in (c) of FIG. 5, to support the lower bump 112. Furthermore, like the upper rubber ring 170, it is possible to place two or more lower rubber rings 180 in one lower housing hole 141.

As shown in FIG. 6, when the upper housing 130 and lower housing 140 are made of an electro-conductive material, an insulating layer 160 may be formed on the inner walls of the upper housing hole 131 and lower housing hole 141 to prevent electrical shorts due to a contact between the upper/lower housing and the electro-conductive member from occurring.

When the insulating layer 160 is formed in the upper housing hole 131 and the lower housing hole 141 as above, the upper rubber ring 170 is disposed such that it does not come into directly contact with the inner wall of the upper housing hole, but rather comes into contact with an inner surface 161 of the insulating layer 160. Similarly, although not shown in the drawing, even when the lower rubber ring 180 is disposed, the lower rubber ring 180 may be disposed such that it does not come into directly contact with the inner wall of the lower housing hole, but rather comes into contact with an inner surface 161 of the insulating layer 160.

Furthermore, although the signal transmission connector 100 according to one embodiment of the present disclosure is described using a configuration in which independently manufactured upper rubber ring 170 and lower rubber ring 180 are mounted on the upper bump 111 and the lower bump 112, respectively, it is also possible to form the upper rubber ring 170 integrally with the upper bump 111 and the lower rubber ring 180 integrally with the lower bump 112 during the process for manufacturing the bumps. That is, a protruding ring having a shape corresponding to the upper rubber ring 170 can be integrally formed on a portion of an outer circumference surface of the upper bump 111, and this protruding ring can be configured to come into contact with the inner wall 132 of the upper housing hole 131. Similarly, a protruding ring having a shape corresponding to the lower rubber ring 180 can be integrally formed on a portion of an outer circumference surface of the lower bump 112, and this protruding ring can be configured to come into contact with the inner wall 142 of the lower housing hole 141. In this way, the upper rubber ring formed integrally with the upper bump and the lower rubber ring formed integrally with the lower bump can achieve the same effect as that obtained by using the upper and lower rubber rings manufactured separately.

Therefore, in the signal transmission connector according to one embodiment of the present disclosure, since the upper bump of the electro-conductive member is aligned with the upper housing by the upper rubber ring, the upper bump may be placed in a correct position to prevent the shift contact from occurring between the upper bump and the terminal of the device under test.

Furthermore, if a configuration, in which the lower bump of the electro-conductive member is aligned with the lower housing by the lower rubber ring, is added, the lower bump may be placed in a correct position to further prevent the shift contact from occurring between the lower bump and the pad of the test board.

In the signal transmission connector according to one embodiment of the present disclosure, since the space between the upper housing hole and the upper bump is blocked by the upper rubber ring and the space between the lower housing hole and the lower bump can also be blocked by the lower rubber ring, the inflow of foreign substances into the above spaces is prevented, thereby preventing contamination of the electro-conductive member by foreign substances, and preventing current leakage caused by contact between the electro-conductive member and foreign substances. Consequently, deterioration of the signal quality of the signal transmission connector can be prevented.

In addition, a space formed by the upper housing 130, the upper rubber ring 170 and the upper bump 111, and a space formed by a gap between the lower housing 140 and the lower bump 112 or a space formed by the lower housing 140, the lower rubber ring 180 and the lower bump 112 may be filled with an air layer A having the relative permittivity of 1. Furthermore, the above spaces may be utilized as a space absorbing an expanded portion of the upper bump 111 and the lower bump 112 of the electro-electric member when the upper bump 111 and the lower bump 112 of the electro-electric member are compressed by the terminal 11 of the device under test,

In the signal transmission connector according to one embodiment of the present disclosure, by filling the space formed by the upper housing, the upper rubber ring and the upper bump, and the space formed by the gap between the lower housing and the lower bump or the space formed by the lower housing and the lower rubber ring and the lower bump with an air layer having the relative permittivity of 1, overall permittivity may be reduced to minimize a signal interference between electro-conductive members, so the signal transmission connector according to one embodiment of the present disclosure can also be usefully used for high-speed signal transmission.

Furthermore, in the signal transmission connector according to one embodiment of the present disclosure, a separate space where the electro-conductive member can be expanded is provided to disperse the pressure applied to the electro-conductive member, thereby preventing damage to the electro-conductive member and extending the life of the signal transmission connector.

FIG. 7 illustrates a test process using the signal transmission connector 100 according to one embodiment of the present disclosure.

As shown in the drawing, when a pressurizing means (not shown) pressurizes the device 10 under test for performing the test, the terminal 11 of the device under test compresses the corresponding electro-conductive member 110 of the signal transmission connector 100 mounted on the test board 20, whereby the test is performed.

When the upper bump 111 of the electro-conductive member is compressed by pressurization of the terminal 11 of the device under test, the upper rubber ring 170 is also compressed, and the upper bump 111 is expanded in a space formed between the inner wall of the upper housing hole and the electro-conductive member. At this time, this compressive force is also transmitted to the lower bump 112 of the electro-conductive member via the connecting bump 113, resulting in the upper bump 111, the connecting bump 113, and lower bump 112 of the electro-conductive member being in electrical communication with each other. In addition, the adjacent electro-conductive members 110 are structurally separated from each other by the upper housing and the lower housing, each electro-conductive member can be compressed independently without affecting the other. As the electro-conductive member is compressed, the signal transmission connector 100 is in a state in which electricity or electrical signal can pass therethrough, this allows the test signal from the test board 20 to be transmitted to the device 10 under test via the signal transmission connector, allowing a test for the device under test to be performed.

Therefore, in the signal transmission connector according to one embodiment of the present disclosure, since the electro-conductive members are disposed and spaced apart from each other in the upper and lower housings made of an inelastic material, each electro-conductive member can be independently and freely compressed or expanded, so the influence due to adjacent electro-conductive members when a test is performed can be minimized and it is possible to minimize the influence of electrical shorts or leakage currents caused by a contact between the electro-conductive members.

Although the present disclosure has been described with reference to preferred examples, the scope of the present disclosure is not limited to the examples described and illustrated above.

In the drawings shown the signal transmission connectors according to the embodiments, although the gap between the upper/lower housing and the electro-conductive member is shown as being constant, it is also possible to design the gap between the upper/lower housing and the electro-conductive member to be uneven, such as by increasing the gap in regions where significant expansion occurs, taking into account the degree of expansion of the electro-conductive member due to compression.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims. The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A signal transmission connector connecting terminals of a device under test to pads of a test board, which generates a test signal, to perform an electrical test for the device under test, the signal transmission connector comprising:
a plurality of electro-conductive members, each of electro-conductive members being formed of an elastic insulating material in which a plurality of electro-conductive particles are arranged in a thickness direction, and having a truncated conical upper bump being able to come into contact with the terminal, an inversed truncated conical lower bump being able to come into contact with the pad, and a cylindrical connecting bump extending between the upper bump and the lower bump;
an insulating support member having an upper surface and an opposite lower surface, and provided with a plurality of support holes formed therein, each of the support holes being coupled with the corresponding connecting bump;
an upper housing formed of an inelastic material, attached to the upper surface of the support member, and having a plurality of upper housing holes, an inner wall constituting each upper housing hole being spaced apart from and surrounding the corresponding upper bump; and
a lower housing formed of an inelastic material, attached to the lower surface of the support member, and having a plurality of lower housing holes, an inner wall constituting each lower housing hole being spaced apart from and surrounding the corresponding lower bump,
wherein a plurality of upper rubber rings are disposed in the upper housing holes, respectively, each of the upper rubber rings has a thickness smaller than that of the upper bump, surrounds an outer circumferential surface of the upper bump, and is in contact with an inner wall of the upper housing hole.

2. The signal transmission connector of claim 1, wherein the upper rubber ring is disposed at an upper side of the upper housing hole.

3. The signal transmission connector of claim 1, wherein the upper rubber ring is formed integrally with the upper bump.

4. The signal transmission connector of claim 1, wherein a plurality of upper rubber rings are disposed in the lower housing holes, respectively, each of the lower rubber ring has a thickness smaller than that of the lower bump, surrounds an outer circumferential surface of the lower bump, and is in contact with an inner wall of the lower housing hole.

5. The signal transmission connector of claim 4, wherein the lower rubber ring is disposed at a lower side of the lower housing hole.

6. The signal transmission connector of claim 4, wherein the lower rubber ring is formed integrally with the lower bump.

7. The signal transmission connector of claim 1, wherein the upper housing and the lower housing are made of an insulating material.

8. The signal transmission connector of claim 1,
wherein the upper housing and the lower housing are made of an electro-conductive material,
wherein an insulating layer is formed on an inner wall of each of the upper housing holes and the lower housing holes,
wherein the upper rubber ring is in contact with an inner circumferential surface of the insulating layer.
